(19) United States
(12) Patent Application Publication
(10) Pub. No.: US 2006/0183250 A1
(43) Pub. Date: Aug. 17, 2006

(54) Methods of fabricating ferroelectric capacitors utilizing a partial chemical mechanical polishing process

(75) Inventors: Suk-Hun Choi, Suwon-si (KR); Byoung-Jae Bae, Suwon-si (KR); Yoon-Ho Son, Yongin-si (KR)

Correspondence Address: HARNESS, DICKEY & PIERCE, P.L.C., P.O. BOX 8910, RESTON, VA, 20195, US

(73) Assignee: Samsung Electronics Co., LTD

(21) Appl. No.: 11/342,842

(22) Filed: Jan. 31, 2006

(30) Foreign Application Priority Data
Feb. 14, 2005 (KR) 10-2005-0012081

(51) Int. Cl. H01L 21/00

(52) U.S. Cl. 438/3

(57) ABSTRACT

The invention provides methods for fabricating ferroelectric capacitors and ferroelectric memory devices incorporating such capacitors. The methods according to the invention each include a partial chemical mechanical polishing process by which a planarized surface may be formed on a material layer formed between a buried contact plug and a ferroelectric layer. In particular, the methods according to the invention compensate for recessed or dishing regions formed in the surface of the buried contact plug to suppress or eliminate the propagation of profile of the recessed or dishing regions through intermediate layers to the ferroelectric layer, thereby improving the ferroelectric performance.

### PRIORITY STATEMENT

This application claims priority under 35 U.S.C. § 119 from Korean Patent Application No. 10-2005-0012081, filed Feb. 14, 2005, the disclosure of which is hereby incorporated herein by reference in its entirety as if set forth fully herein.

### BACKGROUND OF THE INVENTION

1. Technical Field

Example embodiments of the invention relate to methods of fabricating semiconductor devices, including, for example, methods of fabricating ferroelectric memory devices utilizing a partial chemical mechanical polishing process.

2. Discussion of the Related Art

Ferroelectric random access memories (FeRAMs) utilize ferroelectric capacitors as memory cell elements and may be configured for nonvolatile operation. Further, FeRAMs may be configured to provide high operating speeds while operating at low voltage and/or consuming low power. As a result of this combination of features, the interest in FeRAMs for incorporation in the next generation of memory devices is increasing.

Ferroelectric capacitors include at least a lower electrode, an upper electrode and a ferroelectric layer interposed between the lower electrode and the upper electrode. The ferroelectric layer may be formed from a variety of materials including, for example, PZT (Pb(Zr,Ti)O₃), SBT (SrBi₂Ta₂O₉), BTO (BaTiO₃), BFO (BiFeO₃), BST (BaSrTiO₃), BLT ((Bi,La)₄Ti₃O₁₂), SBTN (SrₓBi_{y}(TaᵢNbⱼ)₂O₉) and other materials that exhibit spontaneous polarization under an applied electrical field due to the atomic displacement of the body-centered atom in their perovskite (ABO₃) structure. The ferroelectric materials can have a dielectric constant (κ) of several hundred to several thousand at room temperature and exhibit two stable remnant polarization (Pr) states that make them useful as dielectric films for the fabrication of memory devices, particularly non-volatile memory devices.

Memory devices fabricated with such ferroelectric thin films utilize a hysteresis characteristic for fixing the direction of the remnant polarization for storing digital signals corresponding to ‘1’ and ‘0’ states. The direction of the remnant polarization may be determined by controlling the direction of an applied electric field of sufficient magnitude to set the desired polarization state. The ferroelectric materials will then maintain this polarization state when the electric field is removed.

FIGS. 1A-1C are sectional views illustrating a conventional method of fabricating a ferroelectric memory device. As illustrated in FIG. 1A, after forming a lower structure (not shown) including a gate electrode, and source/drain regions in a semiconductor substrate 5, an interlayer insulating layer 10 may be formed on the overall surface of the semiconductor substrate 5. This interlayer insulating layer 10 may then be selectively etched to form a contact hole 15 that exposes a portion of the semiconductor substrate 5. A metal layer 20, for example a layer of tungsten (W) or other refractory metal, may then be formed on the semiconductor substrate having the contact hole 15. As the metal layer 20 is being formed, the entrance of the contact hole 15 will tend to be covered or sealed by the deposited metal before the contact hole 15 has been completely filled with the metal layer 20, resulting in a centrally located void or seam S.

As the degree of device integration increases, more demanding design rules are being implemented for the semiconductor device fabrication process. These design rules tend to decrease critical dimensions, thereby tending to increase the aspect ratio of the contact holes and other openings formed in dielectric layers. As the aspect ratio of the contact holes increases, the opening will tend to be closed earlier in the deposition of the metal layer, thereby resulting in seam S tending to extend further into the upper portion of the contact hole.

As illustrated in FIG. 1B, the semiconductor substrate having the metal layer 20 may then be planarized using, for example, a chemical mechanical polishing (CMP) process, until an upper surface of the interlayer insulating layer 10 is exposed with a buried contact plug 20a remaining in the contact hole 15. A CMP process may use a slurry incorporating abrasive particles and/or chemical compounds that will provide an etch selectivity enhancing removal of the metal layer 20 relative to removal of the interlayer insulating layer 10. As the interlayer insulating layer 10 is exposed during such a CMP process, the upper portion of the buried contact plug 20a may be subjected to overetching or excessive removal resulting in a dishing region D.

Further, because the seam S may be opened by the lower portion of the dishing region D, the seriousness of the recess phenomenon may increased and, for example, will tend to increase the likelihood of trapping contaminates within the seam during subsequent processing and/or increase the material removed and the depth of subsequent cleaning and/or etch processes.

As illustrated in FIG. 1C, an adhesive layer, an oxidation prevention layer, a lower conductive layer, a ferroelectric layer, and an upper conductive layer may be sequentially formed on the semiconductor substrate above the buried contact plug 20a. Because these layers are generally conformal, the profile of the upper surface of the dishing region D will tend to be replicated to some degree in the subsequently formed layers so that each of the layers will tend to include a recessed portion generally corresponding to the dishing region D.

A capacitor pattern (not shown) may then be formed on the upper conductive layer and used as an etch mask for removing unprotected portions of the upper conductive layer, the ferroelectric layer, the lower conductive layer, the oxidation prevention layer, and the adhesive layer to form a ferroelectric capacitor 48 that is in electrical contact with the buried contact plug 20a. The ferroelectric capacitor 48 may be composed of a lower electrode 37, a ferroelectric pattern 40, and an upper electrode 45, which are sequentially stacked above the substrate. The lower electrode 37 may be composed of an adhesive layer pattern 25, an oxidation prevention layer pattern 30, and a lower conductive layer pattern 35, which are sequentially stacked.

As noted above, when formed above a buried contact plug that includes a dished region D, ferroelectric capacitor 48 tends to exhibit corresponding recessed portions on the upper patterns. In particular as shown in FIG. 1C, the ferroelectric pattern 40 will tend to include portions A which are formed along the recessed portions of the lower conductive layer 35 and will tend to incorporate ferroelectric material in which the crystallographic orientation may be offset, skewed or tilted, e.g., a tilt direction, with respect to the primary vertical orientation exhibited by the remainder of the ferroelectric pattern. Because the polarization direction of the tilted portions A does not coincide with that of other portions of the ferroelectric material, when the ferroelectric pattern 40 is polarized by an applied electric field the hysteresis characteristics of the capacitor are degraded by the tilted portions A. If the tilted portions A are sufficiently large relative to the vertical or untilted portions of the ferroelectric material, the degradation of the hysteresis characteristics may be sufficiently severe to cause failures during the operation of the ferroelectric capacitor.

FIG. 2 is a SEM image illustrating a capacitor region of a ferroelectric memory device fabricated by the conventional method illustrated in FIGS. 1A-1C.

As illustrated in FIG. 2, the ferroelectric capacitor 48 includes recessed portions on the upper portions of the dishing regions D generally corresponding to the structure illustrated in FIG. 1C. In particular, the ferroelectric pattern 40 includes portions A that are formed along the recessed portions of the lower conductive layer 35 and have grown in a tilted or offset direction relative to the remainder of the ferroelectric pattern.

FIGS. 3A and 3B are sectional views illustrating another conventional method of fabricating a ferroelectric memory device developed to address the problems associated with the dishing effects inherent in the fabrication method illustrated in FIGS. 1A-C. As illustrated in FIG. 3A, an interlayer insulating layer 10 may be formed on a semiconductor substrate 5 as described with reference to FIG. 1A. This interlayer insulating layer 10 may then be selectively etched to form a contact hole 15 that exposes a portion of the semiconductor substrate 5. A buried contact plug 20a may then be formed to fill the contact hole 15, however, as noted above with regard to FIGS. 1A and 1B, the aspect ratio of the contact hole tends to result in the formation of a central void or seam S remaining within the buried contact plug 20a. And again, the planarization process for removing the upper portion of the conductive layer will tend to produce a dishing region D in the upper portion of the buried contact plug 20a.

As reflected in FIG. 3A, the buried contact plug 20a may then be subjected to an additional etch back process in order to recess the buried contact plug 20a further relative to the surface of the interlayer insulating layer 10 to form a modified contact plug opening having a reduced aspect ratio. A chemical vapor deposition (CVD) or atomic layer deposition (ALD) process may then be used to form a TiN layer 323 exhibiting improved filling characteristics to fill the upper portion of the buried contact plug hole 15 with a conductive material that does not exhibit the central void or seam S. However, in the course of depositing a TiN layer 323 of sufficient thickness to fill the recessed region completely, for example, 700 Å, stresses generated in the TiN layer can produce a crack C1 that may extend to the interlayer insulating layer 10 as illustrated in FIG. 3A.

As illustrated in FIG. 3B, a planarization process, for example a CMP process, may be used to remove an upper portion of the TiN layer 323 until the interlayer insulating layer 10 is exposed. Because the remaining TiN plug 323a tends to be more resistant to dishing than softer metals, a planarized surface in which the contact plug is not recessed relative to the surface of the interlayer insulating layer may be prepared. A ferroelectric capacitor 348 may then be formed in the manner generally described with reference to FIG. 1C. The ferroelectric capacitor 348 may include a lower electrode 337, a ferroelectric pattern 340, and an upper electrode 345, which may be configured in a stacked structure. The lower electrode 337 may also be configured as a laminated or stacked structure that includes an adhesive layer pattern 325, an oxidation prevention layer pattern 330 and/or a lower conductive layer pattern 335.

Because the ferroelectric pattern 340 is formed on a lower electrode 337 that does not include recessed portions, the ferroelectric pattern 340 can be formed without the tilted portions A illustrated in FIG. 1C and shown in FIG. 2 and will, therefore, tend to exhibit an improved hysteresis characteristic. However, a crack C2 may be generated or remain in the upper portion of the interlayer insulating layer 10 as a result of the crack C1 generated during formation of the TiN layer 323. Thus, although performance improvements may be obtained by reducing or eliminating the tilted regions A, the performance and/or reliability of the semiconductor devices produced by the fabrication process illustrated in FIGS. 3A and 3B may be degraded as a result of crack C2. In addition, the fabrication method as described with regard to FIGS. 3A and 3B requires some additional process steps and/or more complex processing when compared with the conventional fabrication methods corresponding to FIGS. 1A-1C, thereby increasing production costs.

### SUMMARY OF THE INVENTION

Example embodiments of the invention relate to improved methods of fabricating ferroelectric memory devices that include a chemical mechanical polishing (CMP) process for reducing the complexity of the fabrication processes and/or improving the quality of the resulting devices.

Example embodiments of the invention include methods of fabricating ferroelectric memory devices using a partial chemical mechanical polishing CMP process in which an interlayer insulating layer is formed on a semiconductor substrate, contact hole is formed through the interlayer insulating layer to expose a portion of the semiconductor substrate and a metal layer is formed to fill the contact hole. The metal layer is planarized until an upper portion of the interlayer insulating layer is exposed, thereby forming a buried contact plug (BC plug or BCP).

A stacked structure including a lower electrode, which may, in turn, include an adhesive layer, an oxidation prevention layer and/or a lower conductive layer, a ferroelectric layer and an upper conductive layer may be formed on the semiconductor substrate with one of the layers deposited below the ferroelectric layer being subjected to a partial CMP process and thereby form a planarized surface for the subsequent depositions. The stacked structure may then be patterned and the encompassed layers sequentially etched to form a ferroelectric capacitor in electrical contact with the buried contact plug.

If present, the adhesive layer may be formed of one or more conductive materials including metals and metal oxides, for example IrOₓ, TiOₓ, Ti, CeOₓ and/or Ta. If present, the oxidation prevention layer may be formed of one or more materials including metals and metal nitrides, for example, TiAlN, TiN, TaSiN, TaN and/or WN. The lower conductive layer may be composed of one or more materials selected from noble metals and noble metal oxides, for example, platinum (Pt), ruthenium (Ru), iridium (Ir) and/or iridium oxide (IrO₂), which may be deposited as a laminated layer or a composite material layer.

The ferroelectric layer may be formed of one or more ferroelectric materials including, for example, PZT (Pb(Zr,Ti)O₃), SBT (SrBi₂Ta₂O₉), BTO (BaTiO₃), BFO (BiFeO₃), BST (BaSrTiO₃), BLT ((Bi,La)₄Ti₃O₁₂) and/or SBTN (SrₓBi_{y}(TaᵢNbⱼ)₂O₉). Like the lower conductive layer, the upper conductive layer will typically be formed of one or more noble metals and/or noble metal oxides, including, for example platinum (Pt), ruthenium (Ru), iridium (Ir) and/or iridium oxide (IrO₂), which may be deposited as laminated layers or as a composite layer.

Example methods according to the invention may also include forming a buffer layer between the ferroelectric layer and the upper conductive layer. If present, the buffer layer may be formed of strontium ruthenium oxide (SrRuOₓ or SRO) or other suitable material.

Example methods according to the invention may also include an additional deposition of a conductive material layer on the layer selected from the lower electrode for partial planarization with the second deposition being performed after the partial CMP process to compensate to some degree for the material removed in the CMP process. The conductive material may be the same as that of the material removed by the CMP process or may be another compatible conductive material. The thickness of the original deposition of the material may also be increased to provide additional processing margin to compensate to some degree for the material that will be removed during the subsequent CMP process.

The ferroelectric capacitor may be configured as a stacked structure including a lower electrode, a ferroelectric pattern, and an upper electrode. The lower electrode, in turn, may also be configured as a stacked structure including an adhesive layer pattern, an oxidation prevention layer pattern, an optional compensating layer pattern and a lower conductive layer pattern.

The semiconductor memory device may also include the formation of a tungsten metal layer that is deposited on a conformal barrier metal layer on the semiconductor substrate having the contact hole. An example barrier metal layer may include a sequential stack of a titanium layer (Ti) and a titanium nitride layer (TiN).

The interlayer insulating layer may be formed from one or more layers of one or more materials selected from the group consisting of plasma enhanced oxide (PE-Oxide), undoped silicate glass (USG), plasma enhanced tetraethyl orthosilicate (PE-TEOS) and/or high density plasma oxide (HDP-Oxide).

### BRIEF DESCRIPTION OF THE DRAWINGS

The scope of the invention will become more apparent to those of ordinary skill in the art by referring to the detailed description of example embodiments provided below with reference to the attached drawings in which:

FIGS. 1A-1C are cross-sectional views illustrating a conventional method of fabricating a ferroelectric memory device;

FIG. 2 is a SEM image illustrating a capacitor region of a ferroelectric memory device fabricated by the method of FIGS. 1A-1C;

FIGS. 3A and 3B are cross-sectional views illustrating another conventional method of fabricating a ferroelectric memory device;

FIGS. 4A-4G are sectional views illustrating a method of fabricating a ferroelectric memory device according to an embodiment of the invention;

FIGS. 5A-5C are sectional views illustrating a method of fabricating a ferroelectric memory device according to another embodiment of the invention; and

FIGS. 6A-6C are sectional views illustrating a method of fabricating a ferroelectric memory device according to still another embodiment of the invention.

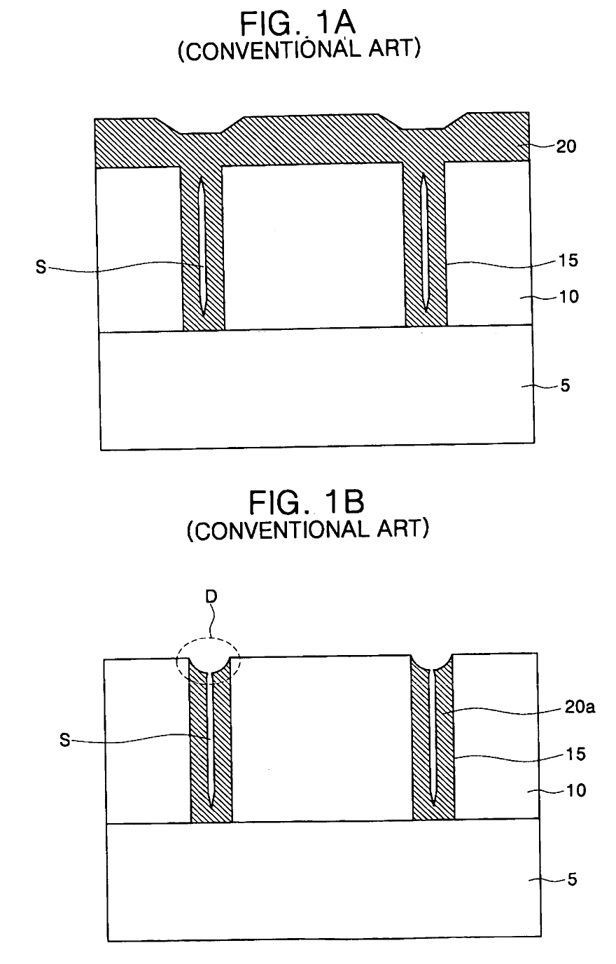

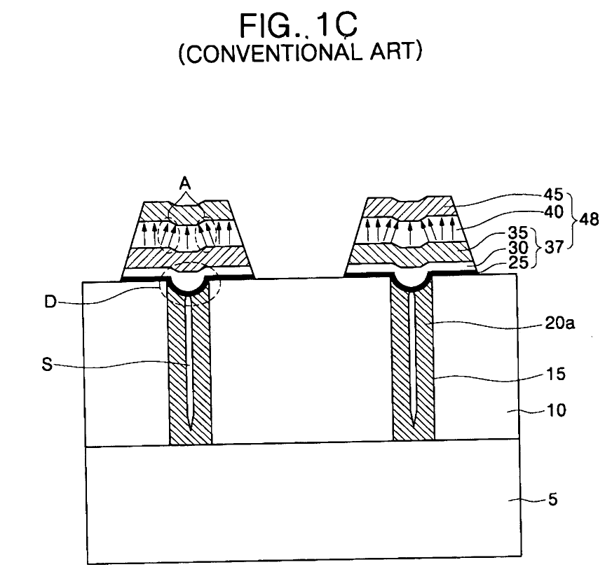

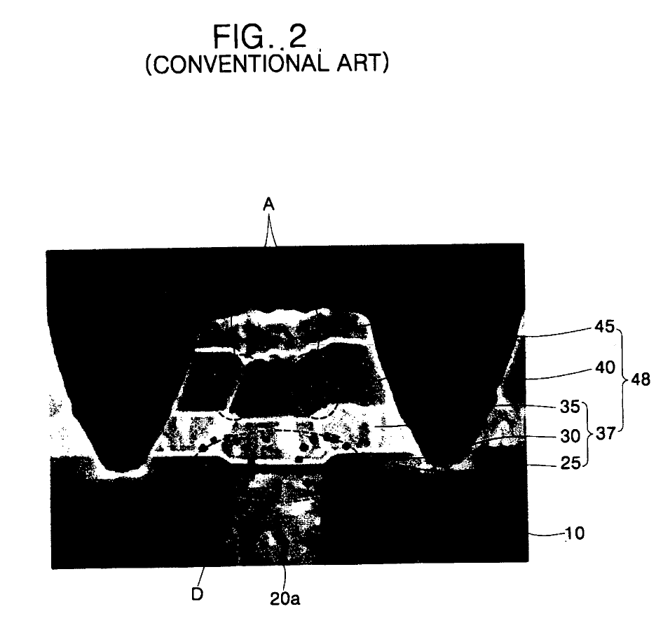

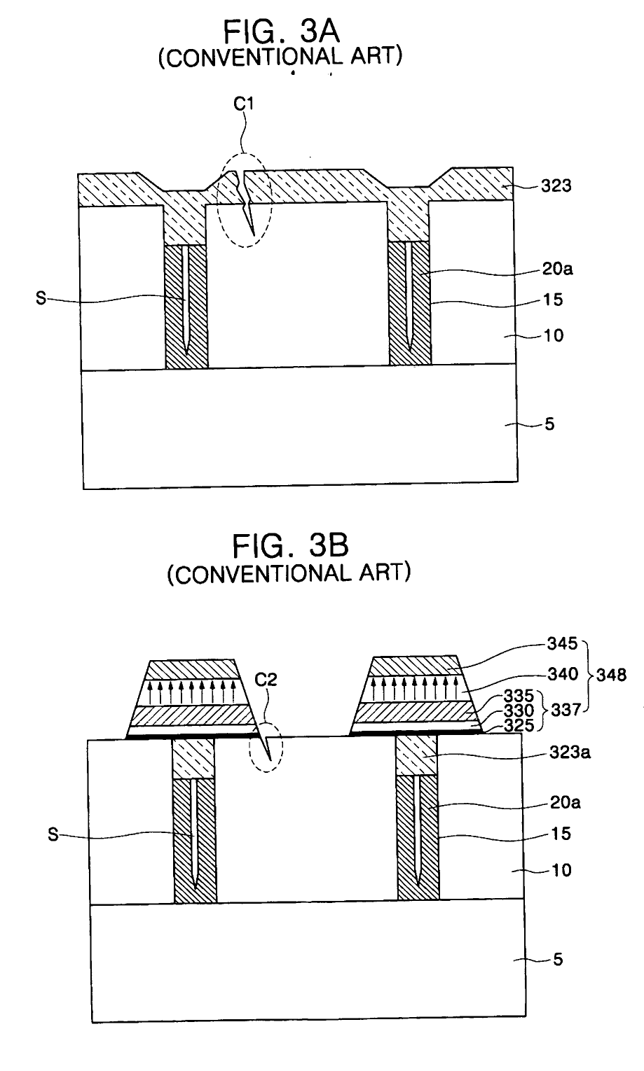

These drawings have been provided to assist in the understanding of certain example embodiments of the invention as described in more detail below and should not be construed as unduly limiting the invention. In particular, the relative spacing, positioning, sizing and dimensions of the various elements illustrated in the drawings are not drawn to scale and may have been exaggerated, reduced or otherwise modified for the purpose of improved clarity.

Those of ordinary skill in the art will also appreciate that a range of alternative configurations have been omitted simply to improve the clarity and reduce the number of drawings. Those of ordinary skill will also appreciate that certain of the various process steps illustrated or described with respect to the example embodiments may be selectively and independently combined to create other methods useful for manufacturing semiconductor devices without departing from the scope and spirit of this disclosure.

### DETAILED DESCRIPTION OF THE INVENTION

Example embodiments of the invention will now be described more fully hereinafter with reference to the accompanying drawings, in which example embodiments of methods according to the invention are shown. Those of ordinary skill in the art will, however, appreciate that this invention may be embodied in many different forms and should not be construed as being limited to the example embodiments illustrated and described herein. Rather, these example embodiments are provided so that this disclosure will be thorough and complete, and will fully convey the scope of the invention to those skilled in the art. Identical or related reference numerals and designations are used throughout the specification and drawings to identify identical and/or corresponding elements of the illustrated structures.

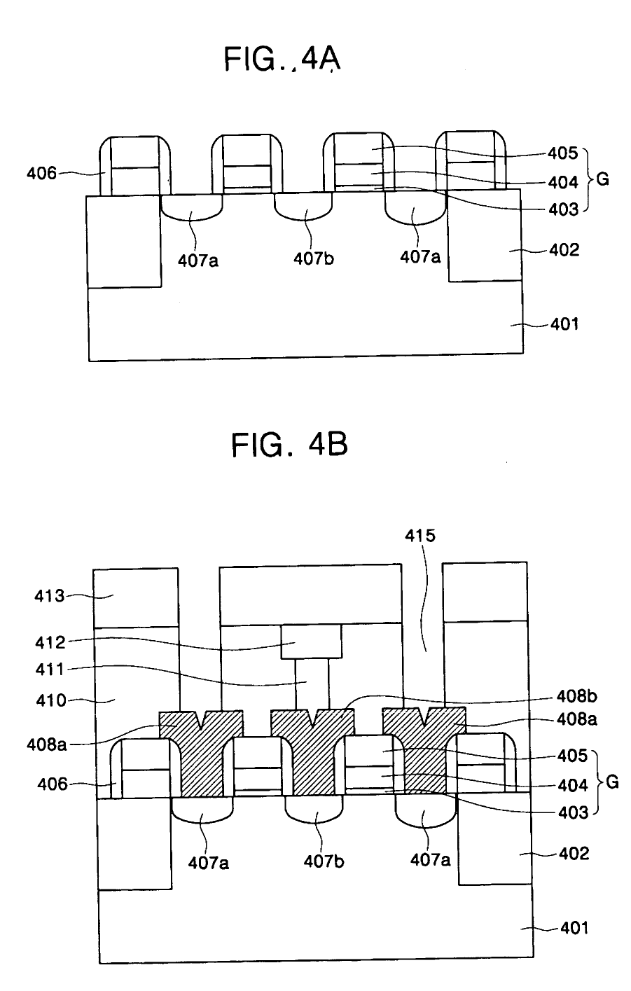

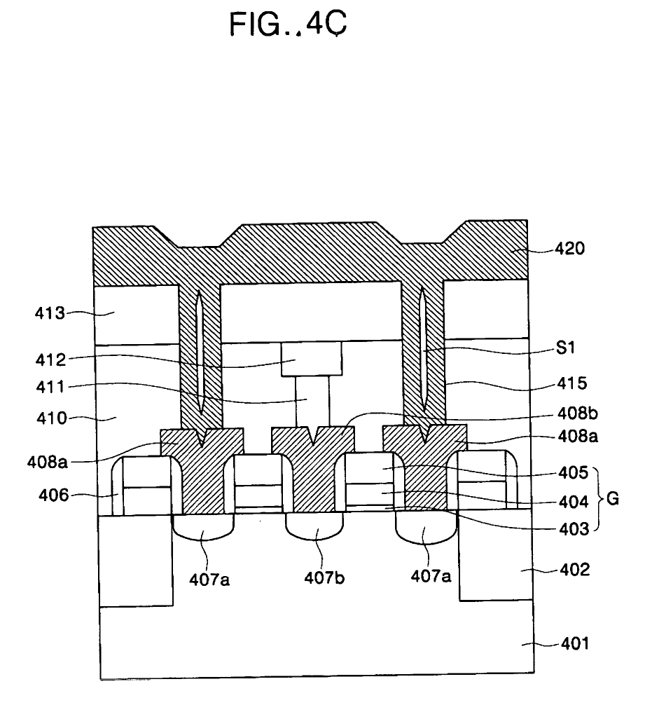

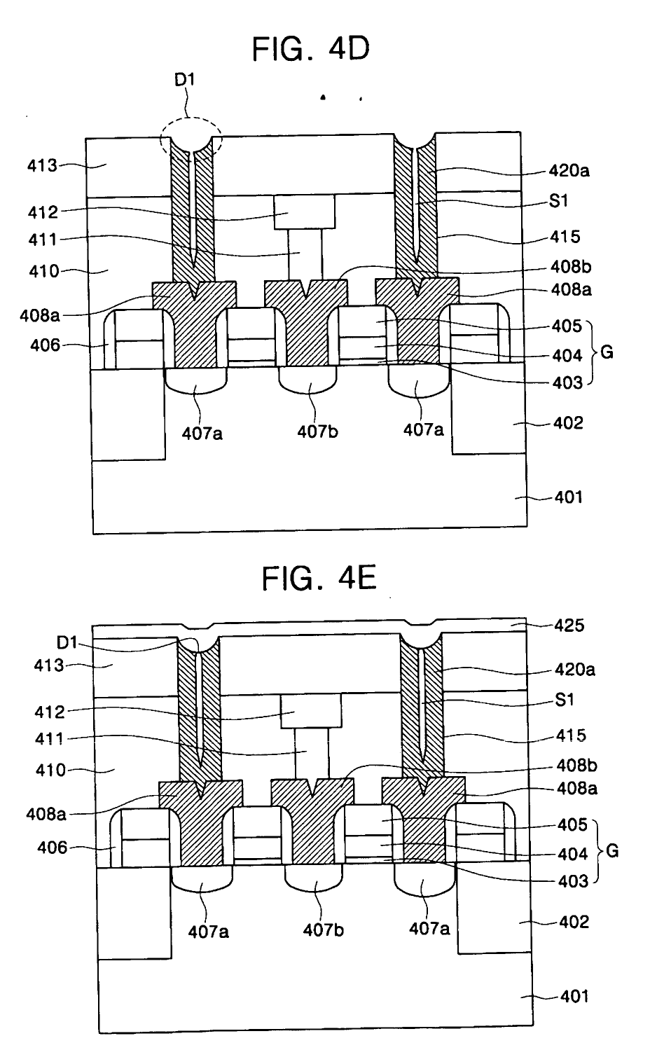

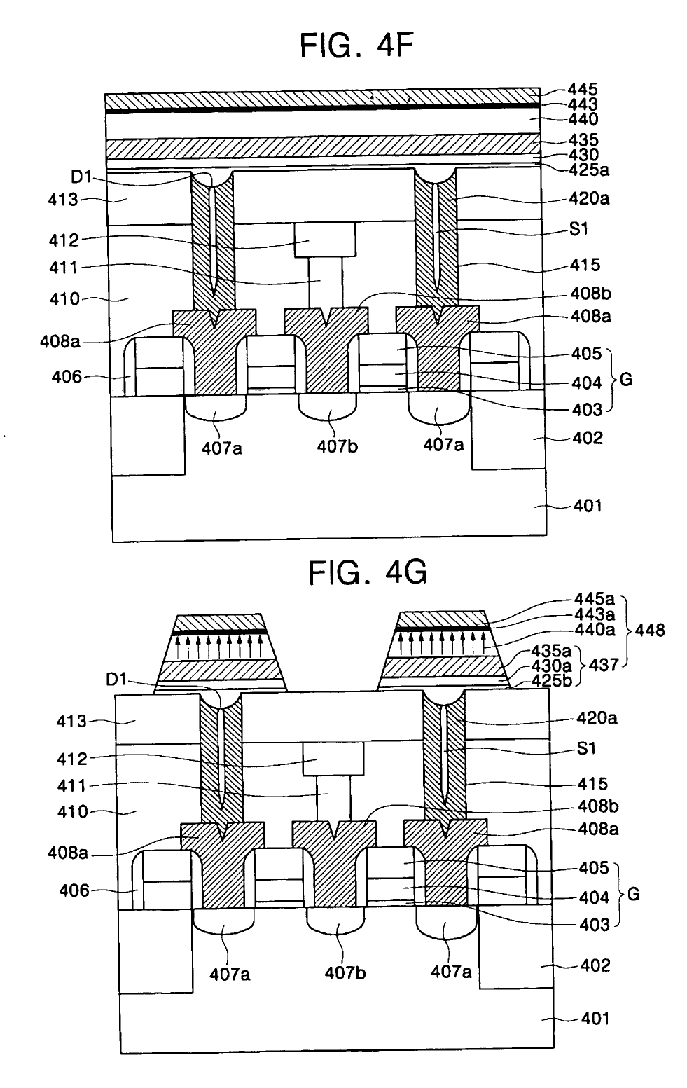

FIGS. 4A-4G are cross-sectional views illustrating an example embodiment of a method of fabricating a ferroelectric memory device. As illustrated in FIG. 4A, an isolation layer 402 defining an active region may be formed in a semiconductor substrate 401. The isolation layer 402 may be formed using a trench isolation technology, for example shallow trench isolation (STI). A gate insulating layer may then be formed on the surface of semiconductor substrate 401, using, for example, a thermal oxidation process or other technique for forming a thin, high-quality dielectric layer. A gate electrode layer may then be formed on the gate insulating layer, using, for example, a doped or undoped polysilicon layer and/or silicide materials and may comprise a composite or laminate structure. A hard mask layer, for example silicon nitride, may then be formed on the gate electrode layer.

The hard mask layer may then be patterned and etched to form a hard mask layer pattern 405 that may be used as an etch mask for etching the unprotected portions of the gate electrode layer to form a gate electrode 404 in the active region. The portion of the gate oxide layer exposed by removing the gate electrode material may also be etched partially or completely during the formation of a gate oxide layer pattern 403. The stacked structure, which may include the gate oxide layer pattern 403, the gate electrode 404 and the hard mask layer pattern 405, constitutes a gate pattern G Gate spacers 406 may then be formed on the sidewalls of the gate pattern G using, for example, a conventional deposition and etchback process. A source region 407a and a drain region 407b may then be formed in the semiconductor substrate, using the gate pattern G and the gate spacers 406 as ion implantation masks. In some instances, a lightly doped drain (LDD) implant may be conducted using only the gate pattern G as the implant mask with another source/drain implant being performed after formation of the gate spacers to provide improved control of the effective channel length.

As illustrated in FIG. 4B, a pad polysilicon layer may then be formed on the semiconductor substrate having the source/drain regions 407a, 407b and gate patterns G This pad polysilicon layer may then be patterned and etched to form pad polysilicon patterns 408a, 408b in contact with the source/drain regions 407a, 407b. A first interlayer insulating layer 410 may then be formed over the semiconductor substrate and the pad polysilicon patterns 408a, 408b. The first interlayer insulating layer 410 may be formed from one or more insulating materials including, for example, undoped silicate glass (USG), plasma enhanced tetraethyl orthosilicate (PE-TEOS) or high density plasma oxide (HDP-Oxide) and may have a generally uniform composition or may be provided as a laminate structure of two or more materials. A direct contact (DC) plug 411 may then be formed through the first interlayer insulating layer (IIL) 410 for establishing electrical contact to the pad polysilicon pattern 408b and, through the pad polysilicon, for providing electrical contact to the drain region 407b. A bit line 412 may then be formed in the first interlayer insulating layer 410 and in electrical contact with the DC plug 411. Both the DC plug 411 and the bit line 412 may be formed from tungsten (W), another refractory metal, metal nitrides, silicides or combinations of such layers.

A second interlayer insulating layer 413 may then be formed on the semiconductor substrate having the bit line 412. The second interlayer insulating layer 413, much like the first interlayer insulating layer, may be formed from one or more layers of insulating materials including, for example, undoped silicate glass (USG), plasma enhanced tetraethyl orthosilicate (PE-TEOS) and/or high density plasma oxide (HDP-Oxide) and may have a generally uniform or laminate structure. An etch mask (not shown) may then be formed on the second interlayer insulating layer 413 and may be used for etching a contact hole 415 through the second interlayer insulating layer and the first interlayer insulating layer 410 are sequentially patterned using a photolithography process, thereby forming contact holes 415 to expose a portion of the pad polysilicon patterns 408a in contact with the source regions 407a.

A modified version (not illustrated) of the example method described above uses a modified mask for etching the pad polysilicon layer so that the material that forms the source pad polysilicon structures 408a is removed. In such instances, additional process steps may be utilized to protect the source regions of the substrate from the etch including, for example, the use of an etch stop layer to reduce or eliminate etch damage and/or post-etch processing to recover or compensate for etch damage that is inflicted on the surface of the source region as the pad polysilicon is removed. In such instances the contact hole 415 may be extended through an additional thickness of the first interlayer insulating layer to expose portions of the source regions 407a of the semiconductor substrate 401.

As illustrated in FIG. 4C, a metal layer 420 may then be formed on the semiconductor substrate having the contact holes 415. The metal layer 420 may be formed from tungsten (W), another refractory metal, metal nitrides, silicides or combinations of such layers. When the metal layer 420 is formed, a central void or seam S1 may be formed if the entrance of the contact hole 415 is sealed or closed before the metal layer 420 has completely filled the inside of the contact hole 415. As the design rules for semiconductor devices are scaled down to provide for more highly integrated devices the aspect ratio of the contact holes and other openings tend to be increased. Accordingly, as the aspect ratio of the contact holes increases, the formation of a central void or seam S1 may become more likely and, if formed, may tend to extend through a greater length of the contact hole, particularly into the upper portion of the contact hole. Before forming the metal layer 420, a conformal barrier metal layer (not shown) may be formed on the semiconductor substrate having the contact hole 415. The barrier metal layer may, for example, be formed by sequentially stacking a titanium (Ti) layer and a titanium nitride (TiN) layer.

As illustrated in FIG. 4D, the semiconductor substrate having the metal layer 420 may then be planarized using a chemical mechanical polishing (CMP) process until a surface of the second interlayer insulating layer 413 is exposed thereby forming a buried contact plug 420a from the portion of the metal layer remaining in the contact hole 415. The CMP process may utilize a slurry composition that incorporates one or more abrasive material(s) and/or chemical compound(s) that will tend to increase the etch selectivity of the metal layer 420 with respect to the second interlayer insulating layer 413. Accordingly, as the surface of the second interlayer insulating layer 413 may be subjected to some degree of over-polishing to compensate for non-uniformity in the thickness or removal of the metal layer, an upper portion of the buried contact plug 420a may removed to a level below the surface of the interlayer insulating layer and form dishing region D1.

If a combination of the depth of the dishing region D1 and the extent of the central void or seam S1 result in opening the seam the is exposed by the dishing region D1, the seriousness of the recess phenomenon may increased and, for example, may tend to increase the likelihood of trapping contaminates within the seam during subsequent processing and/or increase the material removed and the depth of subsequent cleaning and/or etch processes.

As illustrated in FIG. 4E, an adhesive layer 425 may be formed on the semiconductor substrate having the buried contact plug 420a with the thickness of the deposited adhesive layer 425 being selected to fill all the dishing region D1. The adhesive layer 425 may be formed from one or more materials selected from the group consisting of IrOₓ, TiOₓ, Ti, CeOₓ, and Ta and may have a composite or laminated structure.

As illustrated in FIG. 4F, a partial CMP process may then be performed on the semiconductor substrate to remove an upper portion of the adhesive layer 425 without exposing the underlying material to form a planarized adhesive layer 425a. If desired, an additional layer (not shown) of the material used to form the adhesive layer or another compatible material may be formed on the planarized adhesive layer 425a. This additional deposition may be utilized to compensate for or alleviate the effect of defects formed on the surface of the planarized adhesive layer 425a during the CMP process and thereby improve one or more characteristics of the layer.

An oxidation prevention layer 430, a lower conductive layer 435, a ferroelectric layer 440, and an upper conductive layer 445 may then be sequentially formed on the semiconductor substrate having the planarized adhesive layer 425a. An optional buffer layer 443 may also be provided between the ferroelectric layer 440 and the upper conductive layer 445. Because the layers 430, 435, 440, 445 and, optionally 443, are formed on the planarized adhesive layer 425a, they will have a generally planar configuration and will not include recessed regions.

The oxidation prevention layer 430 may be formed from one or more material layer selected from the group consisting of metal nitrides, for example, TiAlN, TiN, TaSiN, TaN, and WN. The lower conductive layer 435 may be composed of one or more materials selected from noble metals and noble metal oxides including, for example, platinum (Pt), ruthenium (Ru), iridium (Ir) and iridium oxide (IrO₂) and may be formed with a laminated layer or a composite layer structure.

The ferroelectric layer 440 may be formed of one or more ferroelectric materials layer selected from a group including, for example, PZT (Pb(Zr,Ti)O₃), SBT (SrBi₂Ta₂O₉), BTO (BaTiO₃), BFO (BiFeO₃), BST (BaSrTiO₃), BLT ((Bi,La)₄Ti₃O₁₂), SBTN (SrₓBi_{y}(TaᵢNbⱼ)₂O₉) and other materials that exhibit spontaneous polarization under an applied electrical field due to the atomic displacement of the body-centered atom in their perovskite (ABO₃) structure. In the case that the ferroelectric layer 440 is composed of a material including lead (Pb) such as PZT and the like, the buffer layer 443 may be formed of a strontium ruthenium oxide (SrRuOₓ or SRO) layer in order to prevent volatility of the lead (Pb). The upper conductive layer 445 may be composed of noble metal or a noble metal oxide. The upper conductive layer 445 may be formed of one material layer selected from the group consisting of platinum (Pt), ruthenium (Ru), iridium (Ir) and iridium oxide (IrO₂), or may be formed of a laminated layer or a composite layer thereof.

As illustrated in FIG. 4G, an etch mask pattern (not shown) may then be formed on the upper conductive layer 445 and used to remove the exposed regions of the upper conductive layer, the optional buffer layer 443 (if present), the ferroelectric layer 440, the lower conductive layer 435, the oxidation prevention layer 430 and the planarized adhesive layer 425a to form ferroelectric capacitors 448 in electrical contact with the buried contact plugs 420a. The ferroelectric capacitor 448 includes a stacked structure including a lower electrode 437, a ferroelectric pattern 440a, optionally, a buffer layer pattern 443a, and an upper electrode 445a. The lower electrode 437 may include a stacked structure including a planarized adhesive layer pattern 425b, an oxidation prevention layer pattern 430a and/or a lower conductive layer pattern 435a.

Because the ferroelectric pattern 440a is formed from a layer of ferroelectric material that was deposited on one or more underlying material layers that were deposited on the planarized adhesive layer 425a, the ferroelectric pattern is etched from a ferroelectric film that has a substantially uniform crystalline orientation. Accordingly, when remnant polarity is induced by exposing the ferroelectric pattern 440a to an electric field of suitable magnitude, the induced polarity is also generally aligned, thereby improving the hysteresis characteristics of the capacitor relative to capacitors that include tilted regions (as described above).

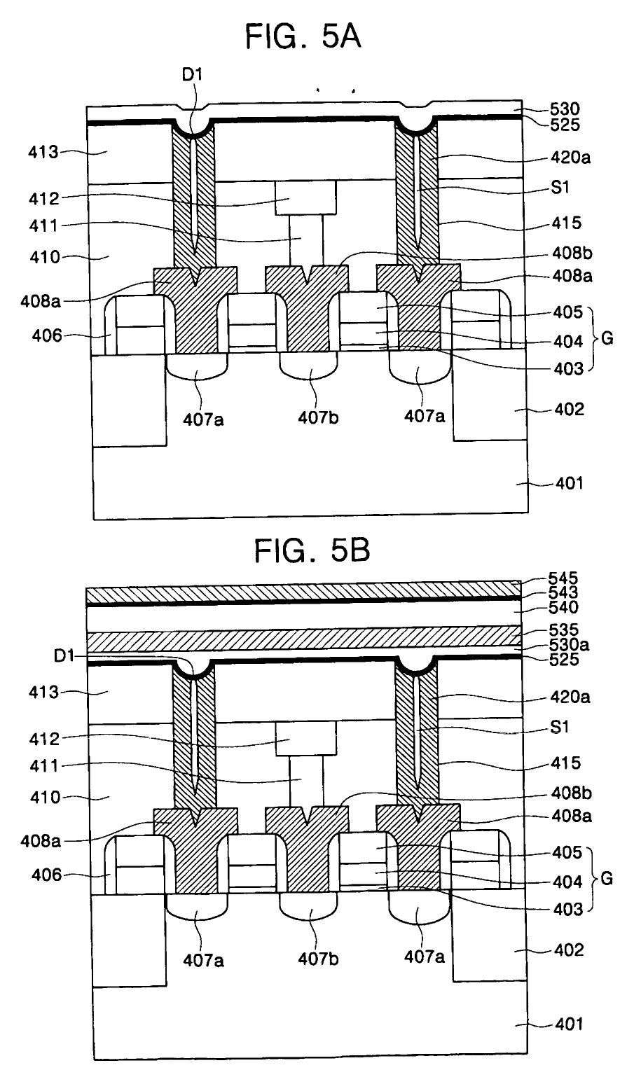

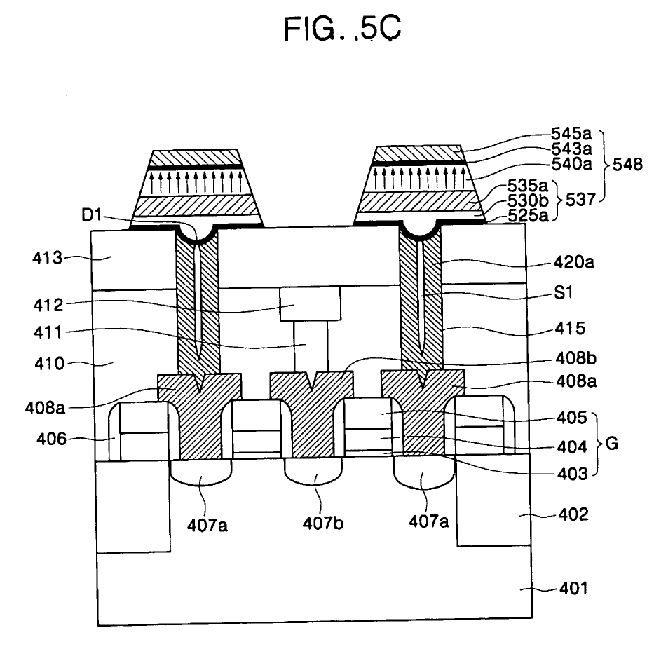

FIGS. 5A-5C cross-sectional views illustrating another example method of fabricating a ferroelectric memory device according to an embodiment of the invention. As illustrated in FIG. 5A, the same processes as described above in reference to FIGS. 4A-4D may be performed until the buried contact plug 420a is formed as indicated by the use of identical reference numerals corresponding to the various elements illustrated in and discussed with regard to FIGS. 4A-4D.

In the example embodiment illustrated in FIGS. 5A-5C, however, an adhesive layer 525 is formed on the semiconductor substrate having the buried contact plug 420a. The adhesive layer 525 may be formed of one or more materials selected from the group consisting of IrOₓ, TiOₓ, Ti, CeOₓ, Ta and combinations thereof and may have a composite or laminated structure. An oxidation prevention layer 530 is formed on the adhesive layer 525 with the thickness of the oxidation prevention layer being sufficient to fill the remaining portion of the dishing region D1 completely. The oxidation prevention layer 530 may be formed from one or more materials providing a sufficient barrier to the migration of oxygen that may, for example, be selected from a group consisting of TiAlN, TiN, TaSiN, TaN, and WN, and may have a composite or laminated structure.

As illustrated in FIG. 5B, a partial CMP process may then be performed on the semiconductor substrate to remove an upper portion of the oxidation prevention layer 530 without exposing the underlying adhesive layer to form a planarized oxidation prevention layer 530a. If desired, an additional layer (not shown) of the material used to form the oxidation prevention layer or another compatible material may be formed on the planarized oxidation prevention layer 530a. This additional deposition may be utilized to compensate for or alleviate the effect of defects formed on the surface of the planarized adhesive layer 530a during the CMP process and thereby improve one or more characteristics of the layer.

A lower conductive layer 535, a ferroelectric layer 540, and an upper conductive layer 545 may then be sequentially formed on the planarized oxidation prevention layer 530a. An optional buffer layer 543 may also be provided between the ferroelectric layer 540 and the upper conductive layer 545. Because the layers 535, 540, 545 and, optionally, 543 are formed on the planarized oxidation prevention layer 530a, they will be formed with a generally planar configuration and thereby reduce or avoid the formation of significantly recessed regions within the upper layers.

The lower conductive layer 535 may be composed of one or more noble metals and/or noble metal oxides including, for example, platinum (Pt), ruthenium (Ru), iridium (Ir) and iridium oxide (IrO₂) and may be formed with a laminated configuration or as a composite layer structure.

The ferroelectric layer 540 may be formed from one or more ferroelectric materials selected from the group including, for example, PZT (Pb(Zr,Ti)O₃), SBT (SrBi₂Ta₂O₉), BTO (BaTiO₃), BFO (BiFeO₃), BST (BaSrTiO₃), BLT ((Bi,La)₄Ti₃O₁₂), SBTN (SrₓBi_{y}(TaᵢNbⱼ)₂O₉) and/or other materials that exhibit spontaneous polarization under an applied electrical field due to the atomic displacement of the body-centered atom in their perovskite (ABO₃) structure. When the ferroelectric layer 540 includes a material including lead (Pb) such as PZT, the buffer layer 543 may be formed from a strontium ruthenium oxide (SrRuOₓ or SRO) layer in order to suppress volatility of the lead. The upper conductive layer 545 may be formed from one or more noble metals or noble metal oxides including, for example, platinum (Pt), ruthenium (Ru), iridium (Ir) and iridium oxide (IrO₂), or may be formed of a laminated layer or a composite layer thereof.

As illustrated in FIG. 5C, an etch mask pattern may be formed on the upper conductive layer 545 and used for the sequential removal of the exposed portions of the upper conductive layer, the buffer layer 543 (if present), the ferroelectric layer 540, the lower conductive layer 535, the planarized oxidation prevention layer 530a, and/or the adhesive layer 525 to form ferroelectric capacitors 548 in contact with the buried contact plugs 420a. The ferroelectric capacitor 548 is a stacked structure including a lower electrode 537, a ferroelectric pattern 540a, optionally a buffer layer pattern 543a, and an upper electrode 545a. The lower electrode 537 may include a stacked configuration including an adhesive layer pattern 525a, a planarized oxidation prevention layer pattern 530b and/or a lower conductive layer pattern 535a.

Because the ferroelectric layer 540 is formed on the planarized oxidation prevention layer 530a, it may be formed as a planarized layer that will generally not include recessed regions in the capacitor region. Accordingly, the ferroelectric pattern 540a may be formed from a ferroelectric film having a substantially uniform crystalline orientation. Accordingly, when remnant polarity is induced by exposing the ferroelectric pattern 540a to an electric field of suitable magnitude, the induced polarity is also generally aligned, thereby improving the hysteresis characteristics of the capacitor relative to capacitors that include tilted regions (as described above).

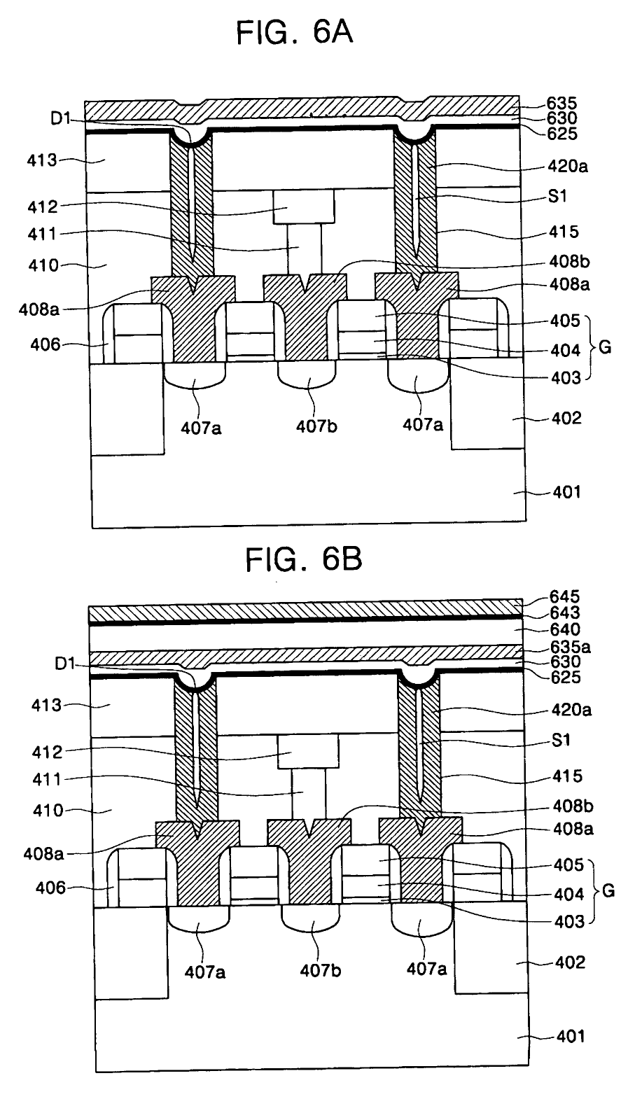

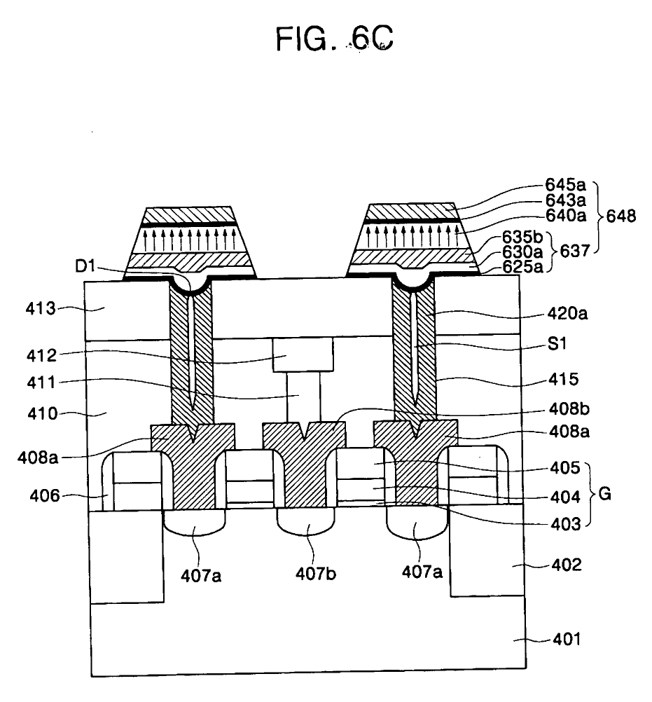

FIGS. 6A-6C are cross-sectional views illustrating a method of fabricating a ferroelectric memory device according to another example embodiment of the invention. As illustrated in FIG. 6A, the same processes as described above in reference to FIGS. 4A-4D may be utilized for forming the underlying substrate structure including a buried contact plug 420a is formed as indicated by the use of identical reference numerals corresponding to the various elements illustrated in and discussed with regard to FIGS. 4A-4D.

An adhesive layer 625, an oxidation prevention layer 630, and/or a lower conductive layer 635 may be formed on the second interlayer insulating layer 413 and the buried contact plug 420a. As deposited on the buried contact structure, the adhesive layer 625, the oxidation prevention layer 630, and the lower conductive layer 635 will each tend to exhibit a recessed area generally corresponding to the dishing region D1 in the buried contact plug 420a.

The adhesive layer 625 may be formed of one or more materials selected from the group consisting of IrOₓ, TiOₓ, Ti, CeOₓ, Ta and other metals and metal oxides that may improve adhesion between the surface of the interlayer insulating layer and the oxidation prevention layer. The oxidation prevention layer 630 may be formed from one or more materials selected from the group consisting of metals and metal nitrides, for example, TiAlN, TiN, TaSiN, TaN, WN or other material that will suppress oxygen migration to or from the layers adjacent the oxidation prevention layer. The lower conductive layer 635 may be formed from one or more noble metals and/or noble metal oxides including, for example, platinum (Pt), ruthenium (Ru), iridium (Ir) and iridium oxide (IrO₂), and may be formed with a laminated layer or a composite layer construction.

As illustrated in FIG. 6B, a partial CMP process may be performed on the semiconductor substrate after deposition of the lower conductive layer 635 to form a planarized lower conductive layer 635a. If desired, an additional layer (not shown) of the material used to form the lower conductive layer or another compatible material may be formed on the planarized lower conductive layer 635a. This additional deposition may be utilized to compensate for or alleviate the effect of defects formed on the surface of the planarized lower conductive layer 635a during the CMP process and thereby improve one or more characteristics of the layer. Further, if the lower conductive layer 635 has a laminated layer structure including two or more different material layers, the CMP planarization process may be modified to remove material from only an upper laminated layer, thereby leaving the lower layer(s) undisturbed by the CMP processing.

A ferroelectric layer 640 and an upper conductive layer 645 may then be sequentially formed on the planarized lower conductive layer 635a. An optional buffer layer 643 may be provided between the ferroelectric layer 640 and the upper conductive layer 645. Because the layers 640, 645 and, optionally, 643 are formed on the planarized lower conductive layer 635a, they may be formed with a generally planar configuration free of recessed regions.

The ferroelectric layer 640 may be formed from one or more ferroelectric materials selected from the group including, for example, PZT (Pb(Zr,Ti)O₃), SBT (SrBi₂Ta₂O₉), BTO (BaTiO₃), BFO (BiFeO₃), BST (BaSrTiO₃), BLT ((Bi,La)₄Ti₃O₁₂), SBTN (SrₓBi_{y}(TaᵢNbⱼ)₂O₉) and other materials that exhibit spontaneous polarization under an applied electrical field due to the atomic displacement of the body-centered atom in their perovskite (ABO₃) structure. When the ferroelectric layer 640 includes a material including lead (Pb) such as PZT, the buffer layer 643 may be formed from a strontium ruthenium oxide (SrRuOₓ or SRO) layer in order to suppress volatility of the lead. The upper conductive layer 645 may be formed from one or more noble metals and/or noble metal oxides including, for example, platinum (Pt), ruthenium (Ru), iridium (Ir) and iridium oxide (IrO₂), and may be formed with a laminated layer or a composite layer.

As illustrated in FIG. 6C, an etch mask pattern (not shown) may then be formed on the upper conductive layer 645 and the upper conductive layer, the buffer layer 643 (if present), the ferroelectric layer 640, the planarized lower conductive layer 635a, the oxidation prevention layer 630, and/or the adhesive layer 625 may then be etched, either sequentially or continuously, to from ferroelectric capacitors 648 in electrical contact with the buried contact plugs 420a. As illustrated in FIG. 6C, the ferroelectric capacitor 648 may include a stacked configuration having a lower electrode 637, a ferroelectric pattern 640a, an optional buffer layer pattern 643a, and/or an upper electrode 645a. The lower electrode 637 may include an adhesive layer pattern 625a, an oxidation prevention layer pattern 630a, and/or a planarized lower conductive layer pattern 635b, provided in a sequentially stacked configuration.

Because the ferroelectric layer 640 is formed on the planarized lower conductive layer 635a, the ferroelectric layer may have a substantially planarized configuration and be relatively free of recessed regions. Accordingly, the ferroelectric pattern 640a may tend to be formed from a ferroelectric film having a substantially uniform crystalline orientation. Accordingly, when remnant polarity is induced by exposing the ferroelectric pattern 640a to an electric field of suitable magnitude, the induced polarity is also generally aligned, thereby improving the hysteresis characteristics of the capacitor relative to capacitors that include tilted regions (as described above).

Further, in addition to the embodiments illustrated in the accompanying figures and described above, an additional conductive layer may be further formed on the laminate lower electrode structure as described above. This additional conductive layer may be utilized as the planarization layer, thereby avoiding disruption of the conventional lower electrode structure while still providing a material layer suitable for partial CMP processing so that the subsequently formed ferroelectric layer may be formed on a generally planar structure and avoid and/or suppress the formation of tilted regions within the ferroelectric layer that would tend to compromise or degrade its performance and that of devices that incorporate such structures.

As described above, the example embodiments according to the invention may include a CMP planarization of one or more material layers formed between the buried contact plug and the ferroelectric layer, thereby compensating for any dishing of the surface of the buried contact plug and providing a generally planar surface for the deposition of the ferroelectric material layer. By providing a generally planar surface for the deposition of the ferroelectric layer, the subsequently formed ferroelectric capacitor will be substantially free of tilted regions, will exhibit more uniform polarization and will exhibit improved hysteresis characteristics. By incorporating these methods into the fabrication process for ferroelectric memory devices, devices exhibiting improved operational performance and/or reliability may be produced.

Although the invention has been described in connection with certain example embodiments, it will be evident to those of ordinary skill in the art that many alternatives, modifications, and variations may be made to the disclosed methods in a manner consistent with the detailed description provided above. Also, it will be apparent to those of ordinary skill in the art that certain aspects of the various disclosed example embodiments could be used in combination with aspects of any of the other disclosed embodiments or their alternatives to produce additional, but not herein illustrated, embodiments incorporating the claimed invention but more closely adapted for an intended use or performance requirements. Accordingly, it is intended that all such alternatives, modifications and variations that fall within the spirit of the invention are encompassed within the scope of the appended claims.

What is claimed is:

1. A method of fabricating a ferroelectric memory device comprising:
forming an interlayer insulating layer on a semiconductor substrate;
forming a contact opening through the interlayer insulating layer;
forming a metal layer on the semiconductor substrate to fill the contact opening;
planarizing the metal layer to form a buried contact plug exhibiting a dished surface in the contact opening;
forming a lower electrode layer having a laminate structure including at least a first material layer and a second material layer;
forming a planarized surface on the lower electrode layer by removing an upper portion of the first or second material layer;
forming a ferroelectric layer on the lower electrode layer;
forming an upper electrode layer on the ferroelectric layer; and
patterning and etching the upper electrode layer, the ferroelectric layer and the lower electrode layer to form a stacked ferroelectric capacitor structure.

2. The method of fabricating a ferroelectric memory device according to claim 1, wherein:
the lower electrode layer is formed by
forming an adhesive layer on the dished surface of the buried contact plug;
forming an oxidation prevention layer on the adhesive layer; and
forming a lower conductive layer on the oxidation prevention layer.

3. The method of fabricating a ferroelectric memory device according to claim 2, wherein forming a planarized surface on the lower electrode layer includes:
performing a partial CMP process on the adhesive layer before forming the oxidation prevention layer.

4. The method of fabricating a ferroelectric memory device according to claim 3, further comprising:
forming another adhesive layer on the planarized surface of the adhesive layer before forming the oxidation prevention layer.

5. The method of fabricating a ferroelectric memory device according to claim 2, wherein forming a planarized surface on the lower electrode layer includes:
performing a partial CMP process on the oxidation prevention layer before forming the lower conductive layer.

6. The method of fabricating a ferroelectric memory device according to claim 5, further comprising:
forming another oxidation prevention layer on the planarized surface of the oxide prevention layer before forming the lower conductive layer.

7. The method of fabricating a ferroelectric memory device according to claim 2, wherein forming a planarized surface on the lower electrode layer includes:
performing a partial CMP process on the lower conductive layer before forming the ferroelectric layer.

8. The method of fabricating a ferroelectric memory device according to claim 7, further comprising:
forming another lower conductive layer on the planarized surface of the lower conductive layer before forming the ferroelectric layer.

9. The method of fabricating a ferroelectric memory device according to claim 2, wherein:
the adhesive layer includes at least one material selected from the group consisting of IrOₓ, TiOₓ, Ti, CeOₓ and Ta.

10. The method of fabricating a ferroelectric memory device according to claim 2, wherein:
the oxidation prevention layer includes at least one material selected from the group consisting of TiAlN, TiN, TaSiN, TaN and WN.

11. The method of fabricating a ferroelectric memory device according to claim 2, wherein:
the lower conductive layer includes a noble metal or a noble metal oxide.

12. The method of fabricating a ferroelectric memory device according to claim 2, wherein:
the lower conductive layer is formed of one material layer selected from a group consisting of platinum (Pt), ruthenium (Ru), iridium (Ir) and iridium oxide (IrO₂).

13. The method of fabricating a ferroelectric memory device according to claim 2, wherein:
the lower conductive layer includes a laminate or composite structure including at least two different material layers selected from a group consisting of platinum (Pt), ruthenium (Ru), iridium (Ir) and iridium oxide (IrO₂).

14. The method of fabricating a ferroelectric memory device according to claim 2, further comprising:
incorporating an additional conductive layer into the lower electrode layer.

15. The method of fabricating a ferroelectric memory device according to claim 1, wherein:
the ferroelectric layer includes at least one material layer selected from the group consisting of PZT (Pb(Zr,Ti)O₃), SBT (SrBi₂Ta₂O₉), BTO (BaTiO₃), BFO (BiFeO₃), BST (BaSrTiO₃), BLT ((Bi,La)₄Ti₃O₁₂) and SBTN (SrₓBi_{y}(TaᵢNbⱼ)₂O₉).

16. The method of fabricating a ferroelectric memory device according to claim 1, wherein:
the upper electrode layer includes a noble metal or a noble metal oxide.

17. The method of fabricating a ferroelectric memory device according to claim 1, wherein:
the upper electrode layer includes at least one material selected from the group consisting of platinum (Pt), ruthenium (Ru), iridium (Ir) and iridium oxide (IrO₂).

18. The method of fabricating a ferroelectric memory device according to claim 1, further comprising:
forming a buffer layer on the ferroelectric layer before forming the upper electrode layer.

19. The method of fabricating a ferroelectric memory device according to claim 18, wherein:
the buffer layer includes strontium ruthenium oxide (SRO).

20. The method of fabricating a ferroelectric memory device according to claim 1, wherein:
the interlayer insulating layer includes at least one insulating material selected from a group consisting of plasma enhanced oxide (PE-Oxide), undoped silicate glass (USG), plasma enhanced tetraethyl orthosilicate (PE-TEOS), and high density plasma oxide (HDP-Oxide) and laminated structures including at least two members of the group.
